(19) United States
(12) Patent Application Publication
(10) Pub. No.: US 2007/0173411 A1
(43) Pub. Date: Jul. 26, 2007

(54) Method of manufacturing substrate for superconducting cable

(75) Inventors: Bong-ki Ji, Yongin-si (KR); Seung Lee, Seoul (KR)

Correspondence Address: MCDERMOTT WILL & EMERY LLP, 600 13TH STREET, N.W., WASHINGTON, DC, 20005-3096, US

(73) Assignee: LS CABLE LTD.

(21) Appl. No.: 11/645,764

(22) Filed: Dec. 27, 2006

(30) Foreign Application Priority Data
Jan. 26, 2006 (KR) 10-2006-0008178

(51) Int. Cl. H01L 39/24

(52) U.S. Cl. 505/238

(57) ABSTRACT

A method of manufacturing a substrate for a superconducting cable has steps of rolling Hastelloy C-276 or stainless steel with a rolling roll having a surface roughness of 10 nm of less which is a value of a root mean square (RMS), thereby forming a substrate; immersing the rolled substrate in an electrolytic polishing solution to electrolytically polish it; and vapor-depositing a superconducting layer on the electrolytically polished substrate. According to the method, it is possible to reduce the time of electrolytic polishing of the substrate, thereby improving the productivity thereof. In addition, it is possible to make the number of cracks per a unit area and the horizontal level favorable.

### CROSS-REFERENCE TO RELATED APPLICATIONS

This application claims all benefits of Korean Patent Application No. 10-2006-8178 filed on Jan. 26, 2006 in the Korean Intellectual Property Office, the disclosures of which are incorporated herein by reference.

### BACKGROUND OF THE INVENTION

1. Field of the Invention

The present invention relates to a method of manufacturing a superconducting cable, and more particularly to a method capable of reducing a time of electrolytic polishing of a substrate, thereby improving productivity thereof.

2. Description of the Prior Art

In general, a superconducting cable has such a property that an electric resistance thereof becomes zero under a critical temperature, so that a high current can flow through it while a loss is minimized. If the superconducting cable is used as a conductor, it is possible to develop a superconducting electric power system such as transformer, motor, generator, fault current limiter and the like. In addition, the superconducting cable can be utilized in many energy, traffic and environmental industries applying an electromagnetic field, such as superconducting power storage, superconducting power transmission cable, superconducting magnetic levitation train, superconducting magnetic separation device and the like.

Examples of a method of manufacturing the superconducting cable are disclosed in U.S. Pat. Nos. 6,103,669, 5,872,080 and 5,661,112.

In manufacturing the superconducting cable, it is needed to reduce a process time of manufacturing a substrate constituting the superconducting cable and to maintain a horizontal level of the substrate during the manufacturing process.

### SUMMARY OF THE INVENTION

Accordingly, the present invention has been made to solve the above problems. An object of the invention is to provide a method of manufacturing a substrate for a superconducting cable, capable of reducing a time of electrolytic polishing of the substrate, improving productivity thereof, decreasing crack occurrence per a unit area and providing an excellent horizontal level.

In order to achieve the above object, there is provided a method of manufacturing a substrate for a superconducting cable, the method comprising steps of rolling Hastelloy C-276 or stainless steel with a rolling roll having a surface roughness of 10 nm of less which is a value of a root mean square (RMS), thereby forming a substrate; immersing the rolled substrate in an electrolytic polishing solution to electrolytically polish it; and vapor-depositing a superconducting layer on the electrolytically polished substrate.

In an embodiment of the invention, a thickness of the substrate formed in the rolling step is preferably 0.05˜0.1 mm. ReBCO may be uses as a material of the superconducting layer.

In an embodiment of the invention, the method may further comprise a step of forming a buffer layer of a metal between the substrate and the superconducting layer so as to preventing a diffusion therebetween.

In addition, in an embodiment of the invention, the method may further comprise a step of forming a protective layer of a metal on the superconducting layer so as to protect the superconducting layer.

### BRIEF DESCRIPTION OF THE DRAWINGS

The above and other objects, features and advantages of the present invention will be more apparent from the following detailed description taken in conjunction with the accompanying drawings, in which:

FIG. 1 is a flow chart showing a method of manufacturing a substrate for a superconducting cable according to an embodiment of the invention.

### DETAILED DESCRIPTION OF THE PREFERRED EMBODIMENTS

Hereinafter, a preferred embodiment of the present invention will be described with reference to the accompanying drawings. In the following description of the present invention, a detailed description of known functions and configurations incorporated herein will be omitted when it may make the subject matter of the present invention rather unclear.

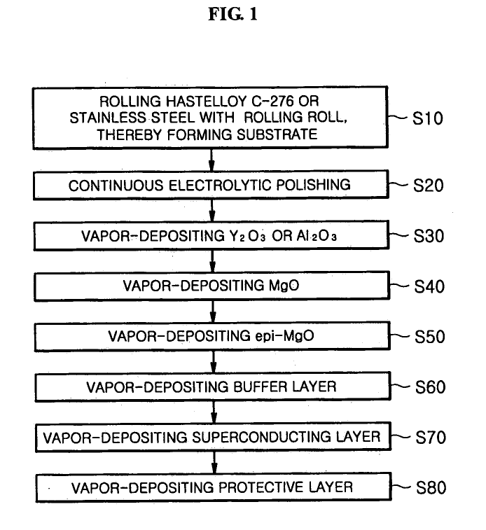

As shown in FIG. 1, a method of manufacturing a substrate for a superconducting cable according to an embodiment of the invention comprise steps of rolling Hastelloy C-276 or stainless steel with a rolling roll having a surface roughness of 10 nm of less which is a value of a root mean square (RMS), thereby forming a substrate having a thickness (t) of 0.05˜0.1 mm and a width (w) of 4˜10 mm (S10); immersing the rolled substrate in an electrolytic polishing solution to electrolytically polish it (S20); and vapor-depositing a superconducting layer and a variety of metal layers on the electrolytically polished substrate (S30˜S80). In the mean time, the processes are sequentially performed as the substrate is moved.

Hereinafter, it will be more specifically described the method of the invention.

First, in order to manufacture a substrate of a superconducting cable, as described above, Hastelloy C-276 or stainless steel (SUS) is rolled with a rolling roll having a surface roughness of 10 nm of less which is a value of a root mean square (RMS), thereby forming a substrate having a thickness of 0.05˜0.1 mm and a width of 4˜10 mm (S10).

Next, the rolled substrate is subject to the electrolytic polishing process (S20). The substrate is electrolytically polished under state that it is immersed in a bath having an electrolytic polishing solution received therein. At this time, as shown in a table 1, the smaller the surface roughness of the rolling roll for rolling the substrate, the shorter the time of the electrolytic polishing of the substrate.

TABLE 1

| | | Sample | | | | |
|---|---|---|---|---|---|---|
| | | 1 | 2 | 3 | 4 | 5 |
| Surface roughness of roll | | 4 | 8 | 12 | 16 | 20 |
| Electrolytic | Time of | 35 sec | 55 sec | 90 sec | 135 sec | 180 sec |
| polishing | condition | | | | | |
| of | 1 | | | | | |
| substrate | Time of | 25 sec | 35 sec | 60 sec | 100 sec | 150 sec |
| | condition | | | | | |
| | 2 | | | | | |

In the table 1, the condition 1 is a case where the electrolytic polishing solution of pH 4 and 20° C. is used, and the condition 2 is a case where the electrolytic polishing solution of pH 2 and 20° C. is used.

When the substrate is immersed in the electrolytic polishing solution for 60 seconds or more, salt is generated on a surface of the substrate, which acts as an impurity to deteriorate a function of the superconducting cable. Due to the reason, it is preferred that it is adopted the rolling roll having the surface roughness of 10 nm or less so as to allow the immersion time of the substrate in the electrolytic polishing solution not to exceed 60 seconds, as shown in the table 1. Herein, the correlation between the immersion time in the electrolytic polishing solution, i.e., 60 seconds and the surface roughness of the rolling roll, i.e., 10 nm was obtained by a number of tests, and the relation of the surface roughness and the time of electrolytic polishing is an example of the tests. For reference, the surface roughness of the substrate which is electrolytically polished in the embodiment is a value of RMS and is 1 nm per 5×5 μm .

In the mean time, it is preferred that the thickness of the substrate is 0.05˜0.1 mm, i.e., 50˜100 μm. As shown in a table 2, when the thickness of the substrate is thinner than 50 μm, a mechanical property is poor, so that there may occur a crack in a vapor deposition layer to be formed in a vapor deposition process. In addition, when the thickness of the substrate is thicker than 100 μm, a mobility of the substrate is lowered, so that a horizontal level of the substrate may be poor during the vapor deposition process.

TABLE 2

| | | Sample | | | | |
|---|---|---|---|---|---|---|
| | | 1 | 2 | 3 | 4 | 5 |
| Thickness (μm) | | 40 | 50 | 80 | 120 | 180 |
| Number of cracks per a meter | One time | 3 | 0 | 0 | 0 | 0 |
| | Three times | 3 | 0 | 0 | 0 | 0 |
| | Five times | 2 | 0 | 0 | 0 | 0 |

| | | | | | |
|---|---|---|---|---|---|
| Horizontal level (angle) during | 0° | 0° | 0° | 0° | 3° |
| vapor deposition | | | | | |

In the table 2, the number of cracks per a meter was measured with naked eyes using an optical microscope. In addition, the horizontal level in the table 2 shows a deviation from an imaginary horizontal line connecting the tops of a pair of guide rollers for guiding both sides of the substrate when the substrate is moved.

When a crack is generated in the substrate, the superconducting function is deteriorated. In addition, when the substrate is slanted, a crystalline structure of the superconducting cable after the vapor deposition is not uniform, so that the superconducting function is deteriorated.

After the electrolytic polishing process, it is performed vapor deposition processes of various metal layers.

First, Y₂O₃ is vapor-deposited on the electrolytically polished substrate in a thickness of 100 Å or Al₂O₃ is vapor deposited thereon in a thickness of 500 Å at a room temperature using an electron beam or ion sputtering (S30).

Then, MgO is vapor-deposited in a thickness of 100 Å at the room temperature in a biaxial culture manner (S40) and epi-MgO is vapor-deposited in a thickness of 500˜1500 Å at a high temperature in the biaxial culture manner (S50). The vapor-deposition of MgO and epi-MgO is performed with the ion sputtering or electron beam using an ion gun.

Next, a buffer layer is vapor-deposited (S60) and a superconducting layer is vapor-deposited thereon (S70).

The buffer layer prevents a diffusion between the metal substrate and the superconducting layer, thereby reducing a lattice mismatch. Tb₂O₃, La₂Zr₂O₇, LaGaO₃, NdGaO₃, YAlO₃, PrGaO₃, KTaO₃ and the like may be uses as the buffer layer. ReBCO (Re=Y, Sm, Ho, Dy) may be used as the superconducting layer.

Finally, a protective layer is vapor-deposited on the superconducting layer (S80) to complete the substrate. The protective layer is a layer for protecting the superconducting layer from the external environment (shock, moisture, etc.) and may consist of Ag, Cu, Pt and the like.

As described above, according to the invention, the thickness of the substrate and the surface roughness are managed to reduce the time of electrolytic polishing process. By reducing the time of electrolytic polishing process, the productivity can be increased.

In addition, it is easy to maintain the horizontal lever during the vapor deposition process. Accordingly, it is possible to maintain a quality of the vapor deposition layer to be uniform in a longitudinal direction and to maintain the proper mechanical property, thereby preventing the crack from being generated in the vapor deposition layer.

While the invention has been shown and described with reference to certain preferred embodiments thereof, it will be understood by those skilled in the art that various changes in form and details may be made thereto without departing from the spirit and scope of the invention as defined by the appended claims.

What is claimed is:

1. A method of manufacturing a substrate for a superconducting cable, the method comprising steps of:
rolling Hastelloy C-276 or stainless steel with a rolling roll having a surface roughness of 10 nm of less which is a value of a root mean square (RMS), thereby forming a substrate;
immersing the rolled substrate in an electrolytic polishing solution to electrolytically polish it; and
vapor-depositing a superconducting layer on the electrolytically polished substrate.

2. The method according to claim 1, wherein a thickness of the substrate formed in the rolling step is preferably 0.05˜0.1 mm.

3. The method according to claim 1, wherein the superconducting layer consists of ReBCO.

4. The method according to claim 1, further comprising a step of forming a buffer layer of a metal between the substrate and the superconducting layer so as to preventing a diffusion therebetween.

5. The method according to claim 1, further comprising a step of forming a protective layer of a metal on the superconducting layer so as to protect the superconducting layer.
